(19) United States
(12) Patent Application Publication
(10) Pub. No.: US 2024/0128195 A1
(43) Pub. Date: Apr. 18, 2024

(54) SEMICONDUCTOR PACKAGE

(71) Applicant: Samsung Electronics Co., Ltd., Suwon-si (KR)

(72) Inventor: Sangwoong Lee, Suwon-si (KR)

(21) Appl. No.: 18/204,970

(22) Filed: Jun. 2, 2023

(30) Foreign Application Priority Data
Oct. 13, 2022 (KR) 10-2022-0131669

(51) Int. Cl. H01L 23/538; H01L 23/00; H01L 23/31; H01L 25/00; H01L 25/065; H01L 25/18; H10B 80/00

(52) U.S. Cl. CPC H01L 23/5386; H01L 23/3128; H01L 23/5383; H01L 24/13; H01L 24/16; H01L 24/19; H01L 24/20; H01L 25/0657; H01L 25/18; H01L 25/50; H10B 80/00; H01L 24/17; H01L 24/32; H01L 24/33; H01L 24/73; H01L 25/16; H01L 2224/13111; H01L 2224/13139; H01L 2224/13147; H01L 2224/16145; H01L 2224/16227; H01L 2224/17181; H01L 2224/32145; H01L 2224/32225; H01L 2224/32245; H01L 2224/33181; H01L 2224/73204; H01L 2224/73253; H01L 2225/06513; H01L 2225/06517; H01L 2225/06541; H01L 2225/06548; H01L 2225/06589; H01L 2924/014

(57) ABSTRACT

A semiconductor package includes a first redistribution structure, a first semiconductor chip disposed on an upper surface of the first redistribution structure, an encapsulant disposed between the first redistribution structure and the first semiconductor chip, a plurality of first conductive posts electrically connecting the first redistribution structure and the first semiconductor chip with each other, and penetrating through the encapsulant in a first direction, a heat dissipation member having at least a portion that overlaps the first semiconductor chip in a second direction that is perpendicular to the first direction, and a second semiconductor chip disposed between the first redistribution structure and the heat dissipation member, and encapsulated by the encapsulant. The first semiconductor chip overlaps the plurality of first conductive posts in the first direction. The first semiconductor chip does not overlap the second semiconductor chip in the first direction.

### CROSS-REFERENCE TO RELATED APPLICATION(S)

This application claims benefit of priority to Korean Patent Application No. 10-2022-0131669 filed on Oct. 13, 2022 in the Korean Intellectual Property Office, the disclosure of which is herein incorporated by reference in its entirety.

### BACKGROUND

The present disclosure relates to a semiconductor package.

In general, a semiconductor chip may be implemented as a semiconductor package such as a wafer level package (WLP) and a panel level package (PLP), and the semiconductor package may be used as an electronic component of a device.

A semiconductor package may include a redistribution layer for electrically connecting a semiconductor chip to a device or a printed circuit board. The redistribution layer may have a structure in which a finer redistribution layer than an interconnection layer of a general printed circuit board extends horizontally.

The redistribution layer may be electrically connected to a bump to vertically extend an electrical connection path, and under bump metallurgy (UBM) may improve the efficiency of electrical connectivity between the redistribution layer and the bump.

As a system provided by a semiconductor chip becomes increasingly complicated and performance of the semiconductor chip gradually increases, a desirable degree of integration of the semiconductor package may gradually increase and a desirable size of the semiconductor package relative to unit performance may decrease. However, as a degree of integration of the semiconductor package increases or a size of the semiconductor package relative to unit performance decreases, a level of difficulty in securing heat dissipation performance of the semiconductor package may increase.

### SUMMARY

The present disclosure provides a semiconductor package capable of more easily securing heat dissipation performance.

According to an aspect of the present disclosure, a semiconductor package includes a first redistribution structure in which at least one first redistribution layer and at least one first insulating layer are alternately stacked, a first semiconductor chip disposed on an upper surface of the first redistribution structure, an encapsulant disposed between the first redistribution structure and the first semiconductor chip, a plurality of first conductive posts electrically connecting the first redistribution structure and the first semiconductor chip with each other, and penetrating through the encapsulant in a first direction, a heat dissipation member having at least a portion that overlaps the first semiconductor chip in a second direction that is perpendicular to the first direction, and a second semiconductor chip disposed between the first redistribution structure and the heat dissipation member, and encapsulated by the encapsulant. The first semiconductor chip overlaps the plurality of first conductive posts in the first direction. The first semiconductor chip does not overlap the second semiconductor chip in the first direction.

According to an aspect of the present disclosure, a semiconductor package includes a first redistribution structure in which at least one first redistribution layer and at least one first insulating layer are alternately stacked, a first semiconductor chip disposed on an upper surface of the first redistribution structure, an encapsulant disposed between the first redistribution structure and the first semiconductor chip, a plurality of first conductive posts electrically connecting the first redistribution structure and the first semiconductor chip with each other, and penetrating through the encapsulant in a first direction, a heat dissipation member having at least a portion that overlaps the first semiconductor chip in a second direction that is perpendicular to the first direction, a second semiconductor chip having at least a portion disposed between the first redistribution structure and the heat dissipation member, and encapsulated by the encapsulant, and a second redistribution structure disposed between the second semiconductor chip and the heat dissipation member. The second redistribution structure includes at least one second redistribution layer and at least one second insulating layer that are alternately stacked on each other.

According to another aspect of the present disclosure, a semiconductor package includes a first redistribution structure in which at least one first redistribution layer and at least one first insulating layer are alternately stacked, a first semiconductor chip disposed on an upper surface of the first redistribution structure, an encapsulant disposed between the first redistribution structure and the first semiconductor chip, a plurality of first conductive posts electrically connecting the first redistribution structure and the first semiconductor chip with each other, and penetrating through the encapsulant in a first direction, a heat dissipation member having at least a portion that overlaps the first semiconductor chip in a second direction that is perpendicular to the first direction, a second semiconductor chip having at least a portion disposed between the first redistribution structure and the heat dissipation member, and encapsulated by the encapsulant, a third semiconductor chip disposed between the second semiconductor chip and the heat dissipation member, and encapsulated by the encapsulant, and a plurality of first bumps disposed on a lower surface of the first redistribution structure, and electrically connected to at least one of the first and second semiconductor chips. The first and second semiconductor chips are electrically connected with each other through the first redistribution structure. The plurality of first conductive posts are disposed on a first region of an upper surface of the first redistribution structure, the first region being adjacent to a first sidewall of the first redistribution structure, and the second semiconductor chip is disposed on a second region of the upper surface of the first redistribution structure, the second region being adjacent to a second sidewall, opposite to the first sidewall, of the first redistribution structure.

According to example embodiments of the present disclosure, a semiconductor package may more easily secure heat dissipation performance.

### BRIEF DESCRIPTION OF DRAWINGS

The above and other aspects, features, and advantages of the present inventive concept will be more clearly understood from the following detailed description, taken in conjunction with the accompanying drawings, in which:

FIGS. 1A to 1D are cross-sectional views illustrating a semiconductor package according to an example embodiment of the present disclosure;

FIGS. 2A to 2C are plan views illustrating a semiconductor package according to an example embodiment of the present disclosure;

FIGS. 3A to 3F are cross-sectional views illustrating a process of manufacturing a semiconductor package according to an example embodiment of the present disclosure; and

FIGS. 4A to 4E are cross-sectional views illustrating a process of manufacturing a semiconductor package according to an example embodiment of the present disclosure.

### DETAILED DESCRIPTION

Detailed description of the present disclosure to be set forth below refers to the accompanying drawings which, by way of example, illustrate specific example embodiments in which the present inventive concept may be practiced. The example embodiments are described in sufficient detail to enable one skilled in the art to practice the present disclosure. It should be understood that the various example embodiments of the present disclosure are different from each other but are not necessarily mutually exclusive. For example, one example embodiment of specific shapes, structures, and characteristics described herein may be implemented in another example embodiment without departing from the spirit and scope of the present disclosure. Additionally, it should be understood that the location or arrangement of individual components within each disclosed example embodiment may be changed without departing from the spirit and scope of the present disclosure. Accordingly, the detailed description set forth below is not intended to be taken in a limiting sense, and the scope of the present disclosure is limited only by the appended claims, with all equivalents as claimed by those claims. Like reference numbers in the drawings indicate the same or similar functions throughout the various aspects.

Hereinafter, example embodiments of the present disclosure will be described in detail with reference to the accompanying drawings, such that those skilled in the art could easily practice the present disclosure.

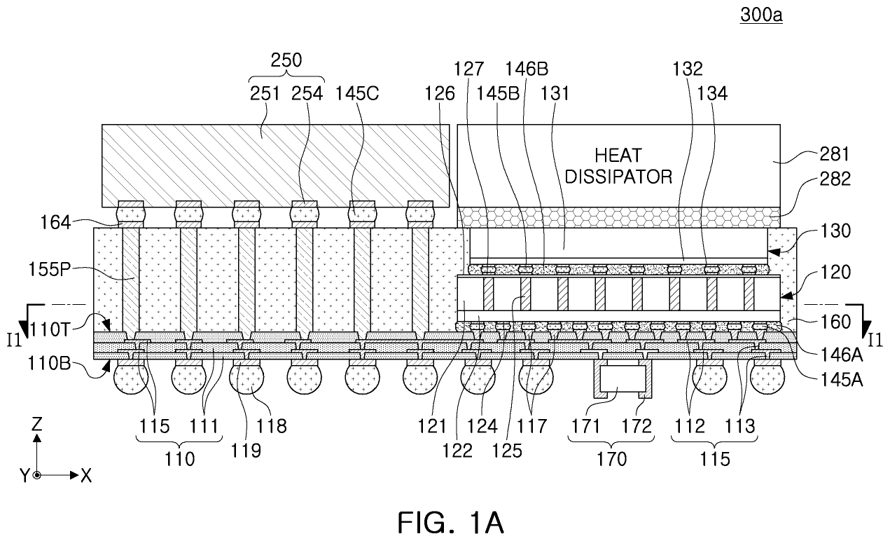

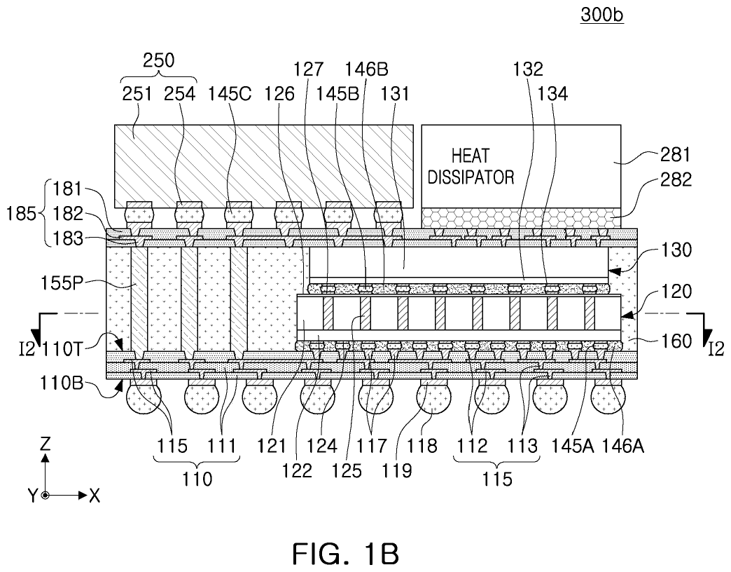

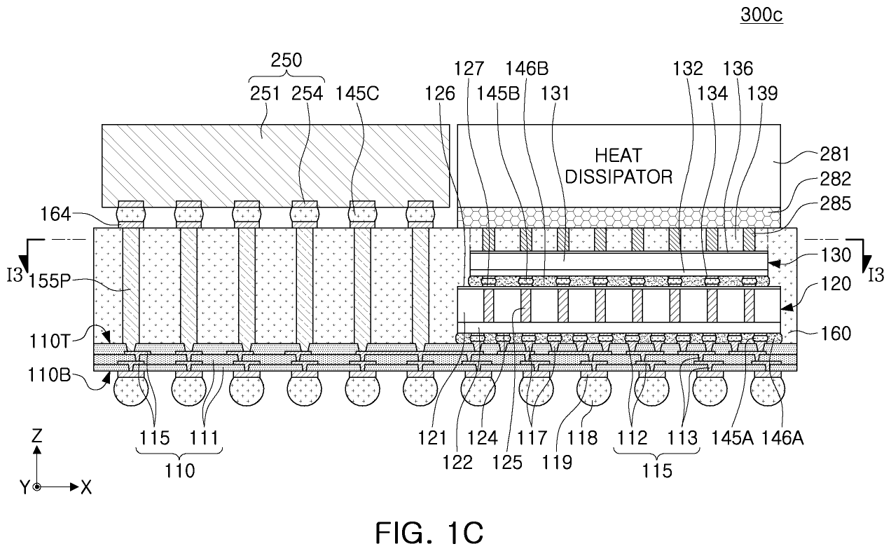

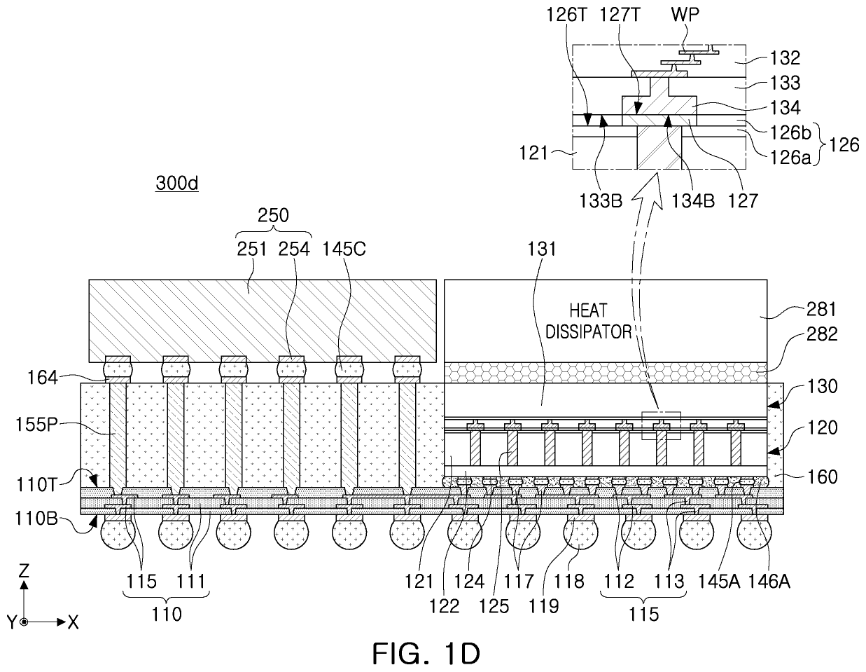

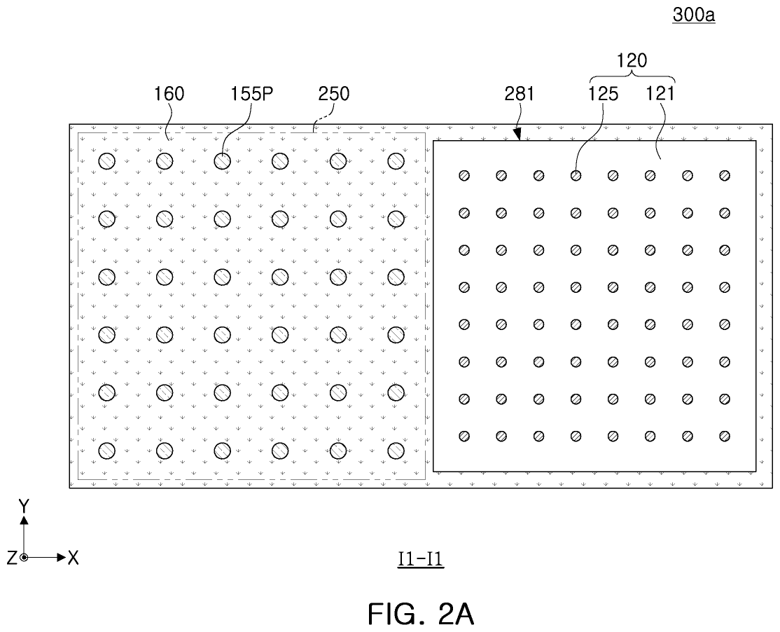

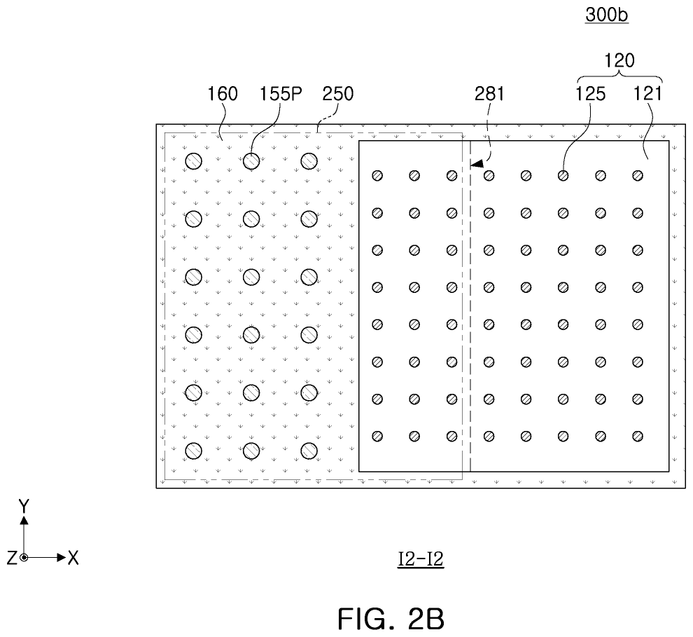

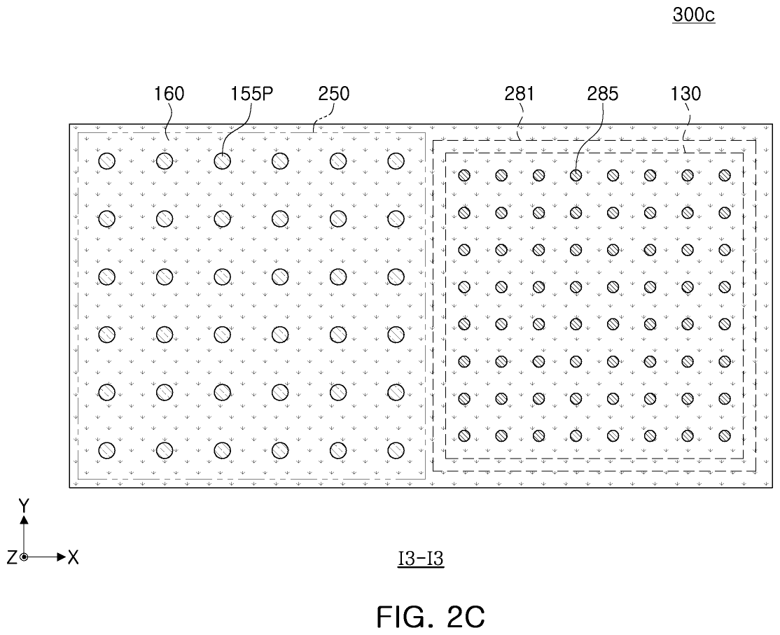

FIG. 1A illustrates a cross-section of a semiconductor package taken on an X-Z plane according to an example embodiment of the present disclosure, and FIG. 2A illustrates a cross-section of the semiconductor package of FIG. 1A taken on an X-Y plane along left and right 1141 of FIG. 1A.

Referring to FIGS. 1A and 2A, a semiconductor package 300a according to an example embodiment of the present disclosure may include a first redistribution structure 110, a first semiconductor chip 250, an encapsulant 160, first conductive posts 155P, a heat dissipation member 281, and a second semiconductor chip 120. The semiconductor package 300a may be a system in package (SIP) including two or more semiconductor chips.

The first redistribution structure 110 may have a structure in which at least one first redistribution layer 112 and at least one first insulating layer 111 are alternately stacked. The first redistribution structure 110 may further include first vias 113 extending from the at least one first redistribution layer 112 in a stacking direction (for example, Z-direction) of the first redistribution structure 110. The first vias 113 may penetrate through the at least one first insulating layer 111.

The at least one first insulating layer 111 may include or may be formed of an insulating material, and may include or may be formed of, for example, a thermosetting resin such as epoxy resin and a thermoplastic resin. In an embodiment, the at least one first insulating layer 111 may include or may be formed of polyimide. For example, the at least one first insulating layer 111 may include or may be formed of a photosensitive insulating material such as a photo imageable dielectric (PID) resin. Alternatively, the at least one first insulating layer 111 may include or may be formed of a resin mixed with an inorganic filler, for example, an Ajinomoto Build-up Film (ABF). Alternatively, the at least one first insulating layer 111 may include or may be formed of prepreg, flame retardant (FR-4), or bismaleimide triazine (BT). The at least one first insulating layer 111 may include or may be formed of the same material or different materials. Depending on a material, a process, and the like of respective layers, a boundary therebetween may not be distinguishable.

The first redistribution layers 112 and the first vias 113 may form first electrical paths 115. The first redistribution layers 112 may be disposed to have a line shape on an X-Y plane, and the first vias 113 may have a cylindrical shape having side surfaces that are inclined such that a width thereof becomes narrower toward a lower portion thereof or an upper portion thereof. The first vias 113 are illustrated as a filled via structure completely filled with a conductive material, but the present disclosure is not limited thereto. For example, the first vias 113 may have a conformal via shape in which a metal material is formed along an inner wall of a via hole.

The first redistribution layers 112 and the first vias 113 may include or may be formed of a conductive material, for example, copper (Cu), aluminum (Al), silver (Ag), tin (Sn), or gold. (Au), nickel (Ni), lead (Pb), titanium (Ti), or alloys thereof.

The first semiconductor chip 250 may be disposed on one surface 110T (i.e., an upper surface) of the first redistribution structure 110, and may be electrically connected to the at least one first redistribution layer 112. For example, the first semiconductor chip 250 may include connection pads 254 disposed on a lower surface of the first semiconductor chip 251, and may be electrically connected to the at least one first redistribution layer 112 through the connection pads 254. For example, the connection pads 254 may include or may be formed of a conductive material such as tungsten (W), aluminum (Al), and copper (Cu), and may be a pad of a bare chip, for example, aluminum (Al) pad. However, in some example embodiments, the connection pads 254 may be a pad of a packaged chip, for example, a copper (Cu) pad.

For example, the first semiconductor chip 251 may include a body portion containing a semiconductor material such as silicon (Si), germanium (Ge), gallium arsenide (GaAs), and the like, and a device layer disposed on a lower portion of the body portion. The device layer may include an integrated circuit (IC). In some embodiments, a plurality of transistors may be formed at the device layer to constitute the IC. In some embodiments, the device layer may further include metal wirings connected to the plurality of transistors to constitute the IC. The first semiconductor chip 251 may include a logic semiconductor chip and/or a memory semiconductor chip. The logic semiconductor chip may be a micro-processor, for example, a central processing unit (CPU), a graphics processing unit (GPU), a field programmable gate array (FPGA), an application processor (AP), a digital signal processor, a cryptographic processor, a controller, or an application specific integrated circuit (ASIC). The memory semiconductor chip may be a volatile memory such as dynamic random access memory (DRAM) and static random access memory (SRAM) or a non-volatile memory such as flash memory.

The encapsulant 160 may be disposed between the first redistribution structure 110 and the first semiconductor chip 250. For example, the encapsulant 160 may contain a molding material such as an epoxy molding compound (EMC). However, a material that may be contained in the encapsulant 160 is not limited to the molding material, and may contain an insulating material having protection properties similar to those of the molding material or high ductility. For example, the insulating material may be a thermosetting resin such as epoxy resin and a thermoplastic resin, and may be an insulating material in which inorganic fillers and/or glass fibers are appropriately added to an insulating material of the first insulating layer 111. In an embodiment, the insulating material may be polyimide.

The first conductive posts 155P may electrically connect the first redistribution structure 110 and the first semiconductor chip 250 with each other and may penetrate through the encapsulant 160. For example, the first conductive posts 155P may be formed prior to the encapsulant 160, and may be formed by a process of plating a metal material (for example, copper) or filling conductive paste in through-holes of a photo resist temporarily formed prior to the encapsulant 160.

At least a portion of the second semiconductor chip 120 may be disposed between the first redistribution structure 110 and the heat dissipation member 281, and may be encapsulated by the encapsulant 160. The second semiconductor chip 120 may be implemented in a manner similar to that of the first semiconductor chip 250. For example, the second semiconductor chip 120 may include a body portion 121 containing a semiconductor material such as silicon (Si), germanium (Ge), gallium arsenide (GaAs), and the like, and a device layer 122 disposed on a lower portion of the body portion 121, the device layer 122 including an integrated circuit (IC). In some embodiments, a plurality of transistors may be formed at the device layer 122 to constitute the IC. In some embodiments, the device layer 122 may further include metal wirings connected to the plurality of transistors to constitute the IC.

For example, the second semiconductor chip 120 may be a logic semiconductor chip, and the first semiconductor chip 251 may be a memory semiconductor chip. The first and second semiconductor chips 250 may be electrically connected with each other through the first redistribution layer 112 of the first redistribution structure 110.

For example, the second semiconductor chip 120 may include connection pads 124 disposed on a lower surface of the second semiconductor chip 120, and may be mounted on an upper surface of the first redistribution structure 110 through the connection pads 124 and bumps 145A in a flip-chip bonding manner. Accordingly, the second semiconductor chip 120 may be electrically connected to the at least one first redistribution layer 112. For example, the bumps 145A may include or may be a solder ball containing tin (Sn) or an alloy (Sn—Ag—Cu) including tin (Sn), and may be surrounded by a non-conductive film layer 146A. The non-conductive film layer 146A may be referred to as an underfill layer, may include or may be formed of a non-conductive polymer such as non-conductive paste (NCP).

At least a portion of the heat dissipation member 281 may be disposed to overlap the first semiconductor chip 250 in a direction (for example, X-direction or a second direction), perpendicular to a direction (for example, Z-direction or a first direction) in which the first conductive posts 155P penetrate through. For example, the heat dissipation member 281 may be formed of a heat slug, and may include a material or may be formed of (for example, gold (Au), silver (Ag), copper (Cu), iron (Fe), graphite, or graphene) having thermal conductivity higher than that of air. For example, copper that may be contained in the heat dissipation member 281 may have a thermal conductivity of approximately 401 W/mk, and air may have a thermal conductivity of approximately 0.025 W/mk. Thus, the heat dissipation member 281 may efficiently dissipate internal heat to the outside. Depending on a design thereof, the heat dissipation member 281 may have a shape having a large area that is in contact with air per volume, thereby efficiently dissipating heat to the outside.

For example, the heat dissipation member 281 may be in contact with and be disposed on an upper surface of a heat transfer material layer 282. The heat transfer material layer 282 may be configured to have a thermal conductivity higher than that of air and lower than that of the heat dissipation member 281 (for example, 2 W/mk to 3 W/mk). Accordingly, the heat transfer material layer 282 may efficiently transfer heat generated by the second and third semiconductor chips 120 and 130 to the heat dissipation member 281. For example, the heat transfer material layer 282 may contain an adhesive polymer, thereby improving adhesion to the heat dissipation member 281, and may contain metal particles dispersed in an adhesive polymer, thereby having increased thermal conductivity. The thermal conductivity of the heat transfer material layer 282 may be determined based on a density of the metal particles that are dispersed in the adhesive layer.

At least a portion of the heat dissipation member 281 may be disposed to overlap the first semiconductor chip 250 in a horizontal direction (for example, an X-direction), and thus may absorb heat generated by the first semiconductor chip 250 and dissipate the absorbed heat to the outside. In addition, the addition of the heat dissipation member 281 to the semiconductor package 300a may not substantially affect a total height of the semiconductor package 300a. Accordingly, the semiconductor package 300a according to an example embodiment of the present disclosure may efficiently use heat dissipation performance of the heat dissipation member 281 and secure an overall degree of integration of the semiconductor package 300a.

The first semiconductor chip 250 may be disposed to overlap the first conductive posts 155P and not to overlap the second semiconductor chip 120 in the direction (for example, Z-direction) in which the first conductive posts 155P penetrate through.

Accordingly, an electrical connection path between the first semiconductor chip 250 and the first redistribution structure 110 may not include a horizontal path, such that an additional redistribution structure may not be necessary between the first semiconductor chip 250 and the encapsulant 160. Accordingly, the semiconductor package 300a according to an example embodiment of the present disclosure may efficiently use the heat dissipation performance of the heat dissipation member 281, may more easily reduce the total height of the semiconductor package 300a, and may further increase a degree of design freedom.

FIG. 1B illustrates a cross-section of a semiconductor package cut in an X-Y plane according to an example embodiment of the present disclosure, and FIG. 2B illustrates a cross-section of the semiconductor package of FIG. 1B in an X-Y plane along left and right I2-I2 of FIG. 1B.

Referring to FIGS. 1B and 2B, a semiconductor package 300b according to an example embodiment may be disposed between the second semiconductor chip 120 and the heat dissipation member 281, and may further include a second redistribution structure 185 in which at least one second redistribution layer 182 and at least one second insulating layer 181 are alternately stacked. The semiconductor package 300b may have a package on package (POP) structure.

The second redistribution structure 185 may be implemented in a manner similar to that of the first redistribution structure 110, and may include second vias 183. A combination structure of the at least one second redistribution layer 182 and the second vias 183 may be an electrical connection path. For example, the number of layers (for example, one) of the at least one second redistribution layer 182 may be less than the number of layers (for example, two) of the at least one first redistribution layer 112.

The second redistribution structure 185 may provide a horizontal path to an electrical connection path between the first semiconductor chip 250 and the first redistribution structure 110. Accordingly, the first conductive posts 155P may be arranged in a more compact manner (for example, in such a way that an interval becomes narrower), and thus a total horizontal area of the semiconductor package 300b according to an example embodiment of the present disclosure may be effectively reduced.

For example, a portion (for example, a right portion) of the first semiconductor chip 250 may overlap a portion (for example, a left portion) of the second semiconductor chip 120 in a direction (for example, Z-direction) in which the first conductive posts 155P penetrate through. The second redistribution structure 185 provides a horizontal path to an electrical connection path between the first semiconductor chip 250 and the first redistribution structure 110.

In addition, the heat dissipation member 281 may be disposed on an upper surface of the second redistribution structure 185 as a component, such that structural compatibility of the heat dissipation member 281 with respect to the semiconductor package 300b may be increased. When the compatibility is increased, a degree of design freedom (for example, ease of size optimization and a weight limit range) of the heat dissipation member 281 may be further increased, and an overall degree of integration of the semiconductor package 300b may be further increased.

For example, a size of a surface (for example, a lower surface) of the heat dissipation member 281 opposing the second semiconductor chip 120 may be smaller than a size of a surface (for example, a lower surface) of the first semiconductor chip 250 opposing the first conductive posts 155P. Such a structure may be a structure according to an increased degree of design freedom of the heat dissipation member 281.

Referring to FIGS. 1A to 1C, semiconductor packages 300a, 300b, and 300c according to an example embodiment of the present disclosure may further include a third semiconductor chip 130 disposed between the second semiconductor chip 120 and the heat dissipation member 281 and encapsulated by the encapsulant 160.

The third semiconductor chip 130 may be implemented in a manner similar to those of the first and second semiconductor chips 250 and 120. For example, the third semiconductor chip 130 may include a body portion 131 implemented in a manner similar to that of the body portion 121, and a device layer 132 implemented in a manner similar to that of the device layer 122, may include connection pads 134 implemented in a manner similar to that of the connection pads 124, may include bumps 145B implemented in a manner similar to that of the bumps 145A, and may be mounted on an upper surface of the second semiconductor chip 120. The bumps 145B may be surrounded by a non-conductive film layer 146B implemented in a manner similar to that of the non-conductive film layer 146A.

For example, the second semiconductor chip 120 may further include through-vias 125, an intermediate dielectric layer 126, and connection pads 127. The connection pads 127 and the intermediate dielectric layer 126 may be disposed on an upper surface of the second semiconductor chip 120. The bumps 145B may be in contact with both the connection pads 127 and the connection pads 134, and may be disposed between the connection pads 127 and the connection pads 134. The through-vias 125 may penetrate through the body portion 121, and may be electrically connected between the device layer 122 and the connection pads 127. The through-vias 125 may be formed of a conductive material, and may include or may be formed of, for example, at least one of tungsten (W), aluminum (Al), and copper (Cu).

A horizontal size of a combination structure (3D integrated circuit structure) of the second and third semiconductor chips 120 and 130 may be similar to a horizontal size of one semiconductor chip. A total volume (corresponding to circuit performance) and total heat generation of the device layers 122 and 132 of the second and third semiconductor chips 120 and 130 may be about twice a volume and heat generation of a device layer of one semiconductor chip. Accordingly, when compared to one semiconductor chip, a density of electrical connection paths of the combination structure of the second and third semiconductor chips 120 and 130 with respect to the first redistribution structure 110 may be higher, and it may be more difficult to prepare a space for disposing a heat dissipation member around the third semiconductor chips 120 and 130.

Depending on an arrangement relationship between the heat dissipation member 281 and adjacent structures, the heat dissipation member 281 may not be affected by a high density of an electrical connection path of a structure in which the second and third semiconductor chips 120 and 130 are vertically coupled with each other. The semiconductor packages 300a, 300b, and 300c according to an example embodiment of the present disclosure may have high circuit performance per unit volume while obtaining efficient heat dissipation performance.

Referring to FIGS. 1A and 1B, the third semiconductor chip 130 may be exposed toward the heat dissipation member 281 such that the encapsulant 160 does not block a space between the third semiconductor chip 130 and the heat dissipation member 281. Accordingly, the third semiconductor chip 130 may be in contact with the heat transfer material layer 282 or the second redistribution structure 185, and heat generated by the second and third semiconductor chips 120 and 130 may be more efficiently transferred to the heat dissipation member 281. For example, the encapsulant 160 may cover a sidewall of the third semiconductor chip 130 without covering an upper surface of the third semiconductor chip 130. The upper surface of the third semiconductor chip 130 may be adjacent to the heat dissipation member 281, and a lower surface of the third semiconductor chip 130 may be adjacent to an upper surface of the second semiconductor chip 120. In an embodiment, an upper surface of the encapsulant 160 may be coplanar with the upper surface of the third semiconductor chip 130.

FIG. 1C illustrates a cross-section of a semiconductor package taken on an X-Z plane according to an example embodiment of the present disclosure, and FIG. 2C illustrates a cross-section of the semiconductor package of FIG. 1C in an X-Y plane along left and right I3-13 of FIG. 1C.

Referring to FIGS. 1C and 2C, the semiconductor package 300c according to an example embodiment may further include second conductive posts 285 disposed between the second semiconductor chip 120 and the heat dissipation member 281. The second conductive posts 285 may extend in a direction (for example, Z-direction) in which the second semiconductor chip 120 and the heat dissipation member 281 oppose each other. The second conductive posts 285 may be electrically connected to the heat dissipation member 281. In some embodiments, the second conductive posts 285 may be thermally connected to the heat dissipation member 281 so that heat generated from the second and third semiconductor chips 120 and 130 may be transferred to the heat dissipation member 281 via the second conductive posts 285.

The second conductive posts 285 may be implemented in a manner similar to that of the first conductive posts 155P. Accordingly, whether or not the second conductive posts 285 are added may not increase overall process complexity of the semiconductor package 300c.

The second conductive posts 285 may connect the heat transfer material layer 282 and the third semiconductor chip 130 with each other, and may be used as a path through which heat generated by the second and third semiconductor chips 120 and 130 is transferred to the heat dissipation member 281. Accordingly, even when the third semiconductor chip 130 is not in contact with the heat transfer material layer 282 or the second redistribution structure 185, the heat dissipation member 281 may efficiently absorb the heat generated by the second and third semiconductor chips 120 and 130. For example, the second conductive posts 285 may thermally connect the second and third semiconductor chips 120 and 130 to the heat transfer material layer 282.

For example, the third semiconductor chip 130 may include an intermediate dielectric layer 136 disposed on an upper surface of the third semiconductor chip 130, and the second conductive posts 285 may extend upwardly from an upper surface of the intermediate dielectric layer 136. For example, the second conductive posts 285 may be surrounded by a mold layer 139. The mold layer 139 may contain the same material as a molding material (for example, EMC) that may be included in the encapsulant 160 or may contain an insulating material having properties similar to those of the molding material.

Referring to FIGS. 1A to 1D, the first conductive posts 155P may be disposed to be biased in a first direction (for example, −X direction) from a center of the encapsulant 160, and second and third semiconductor chips 120 and 130 may be disposed to be biased from the center of the encapsulant 160 in a second direction (for example, +X direction), opposite to the first direction. Accordingly, an arrangement space of the heat dissipation member 281 and an arrangement space of the first semiconductor chip 250 may be effectively divided from each other. In an embodiment, the first conductive posts 155P may be disposed on a first region of an upper surface of the first redistribution structure 110, the first region being adjacent to a first sidewall of the first redistribution structure 110. The second semiconductor chip 120 may be disposed on a second region of the upper surface of the first redistribution structure 110, the second region being adjacent to a second sidewall, opposite to the first sidewall, of the first redistribution structure 110.

Referring to FIGS. 1A to 1D, semiconductor packages 300a, 300b, 300c, and 300d according to an example embodiment of the present disclosure may further include first bumps 118 disposed on the other surface 110B (i.e., a lower surface) of the first redistribution structure 110, and electrically connected to at least one of the first and second semiconductor chips 250 and 120. For example, the first bumps 118 may have a ball or column shape, and may include or may be a solder ball containing tin (Sn) or an alloy (Sn—Ag—Cu) including tin (Sn). The first bumps 118 may have a relatively low melting point, as compared to other metal materials, and thus may be connected and fixed to UBM structures 119 of the semiconductor packages 100a, 100b, 100c, and 100d by a thermal compression bonding (TCB) process or a reflow process.

The UBM structures 119 may be disposed on the other surface 110B (i.e., a lower surface) of the first redistribution structure 110, and the UBM structures 164 may be disposed on an upper surface of the encapsulant 160 or the second redistribution structure 185. The UBM structures 117 may be disposed on an upper surface 110T of the first redistribution structure 110, and may be formed by a semi-additive process (SAP).

Referring to FIGS. 1A to 1D, the semiconductor packages 300a, 300b, 300c, and 300d according to an example embodiment of the present disclosure may further include second bumps 145C electrically connected between the first conductive posts 155P and the first semiconductor chip 250. The second bumps 145C may overlap the first conductive posts 155P in a direction (for example, Z-direction) in which the first conductive posts 155P penetrate through. The second bumps 145C may be implemented in a manner similar to that of the first bumps 118.

Referring to FIG. 1A, the semiconductor package 300a according to an example embodiment of the present disclosure may further include an impedance element 170 disposed on the other surface 110B of the first redistribution structure 110. The impedance element 170 may provide impedance (capacitance, inductance, and resistance) to the first to third semiconductor chips 250, 120, and 130, thereby improving signal reliability (for example, signal integrity and power integrity) of the first to third semiconductor chips 250, 120, and 130.

For example, the impedance element 170 may be a multilayer ceramic capacitor (MLCC) or a coil component, and may include an impedance body 171 and external electrodes 172. The impedance element 170 may have impedance generated by the impedance body 171 for the first redistribution structure 110 through the external electrodes 172.

Referring to FIG. 1D, the semiconductor package 300d according to an example embodiment of the present disclosure may further include an additional intermediate dielectric layer 133 and additional connection pads 134, and the intermediate dielectric layer 126 may include intermediate dielectric layers 126a and 126b that are stacked on each other.

The connection pads 127 and the additional connection pads 134 may be buried in the intermediate dielectric layer 126 and the additional intermediate dielectric layer 133, respectively, and thus may not be exposed to the encapsulant 160. Such a structure may be represented by hybrid bonding. For example, the intermediate dielectric layer 126 and the additional intermediate dielectric layer 133 may contain at least one of silicon oxide (SiO), silicon nitride (SiN), and silicon carbonitride (SiCN).

For example, before the second semiconductor chip 120 and the third semiconductor chip 130 are coupled with each other, the intermediate dielectric layer 126 and the additional intermediate dielectric layer 133 may be disposed in the second semiconductor chip 120 and the third semiconductor chip 130, respectively. Thereafter, the intermediate dielectric layer 126 and the additional intermediate dielectric layer 133 may be bonded with each other, and accordingly the second semiconductor chip 120 and the third semiconductor chip 130 may be bonded with each other. In this case, the connection pads 127 and the additional connection pads 134 may be bonded with each other through interfaces 127T and 134B.

For example, the intermediate dielectric layers 126a and 126b may be bonded with each other through the interfaces 126T and 133B. Upper surfaces of the through-vias 125 and the interfaces 126T and 133B may form one plane. The additional connection pads 134 may be connected to an interconnection pattern WP of the device layer 132.

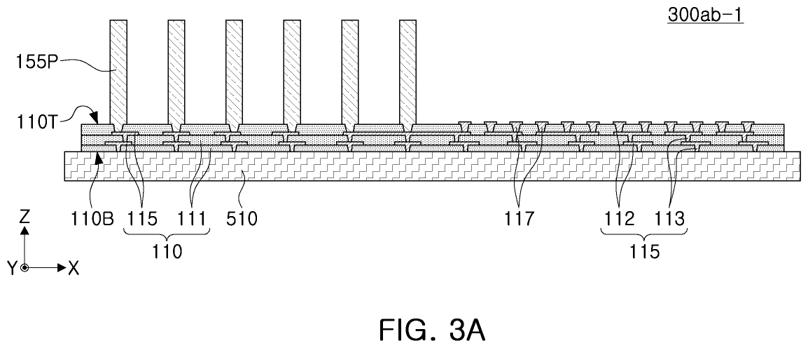

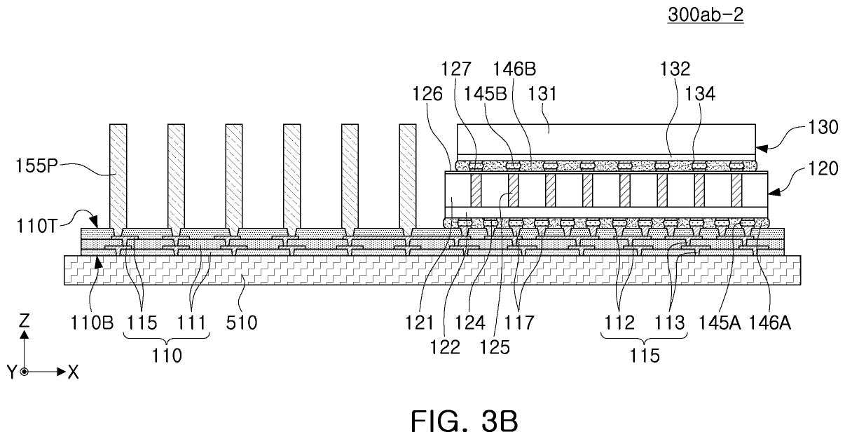

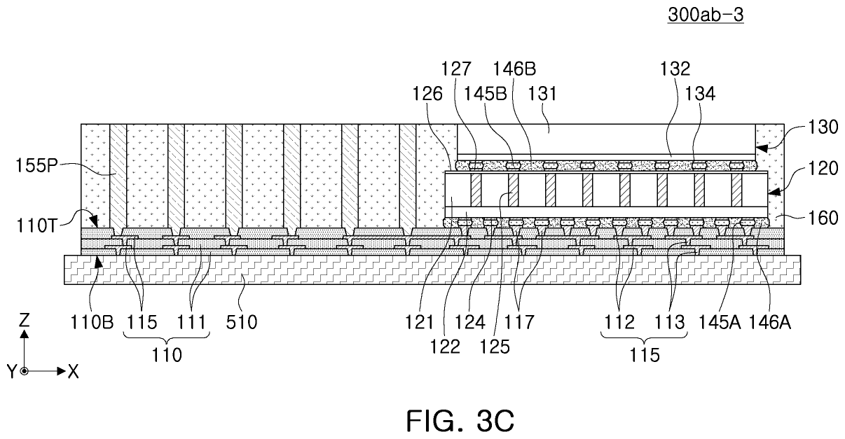

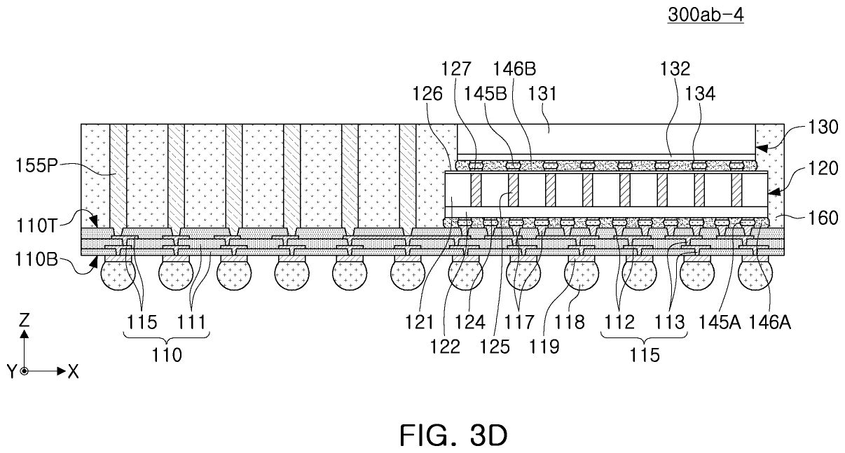

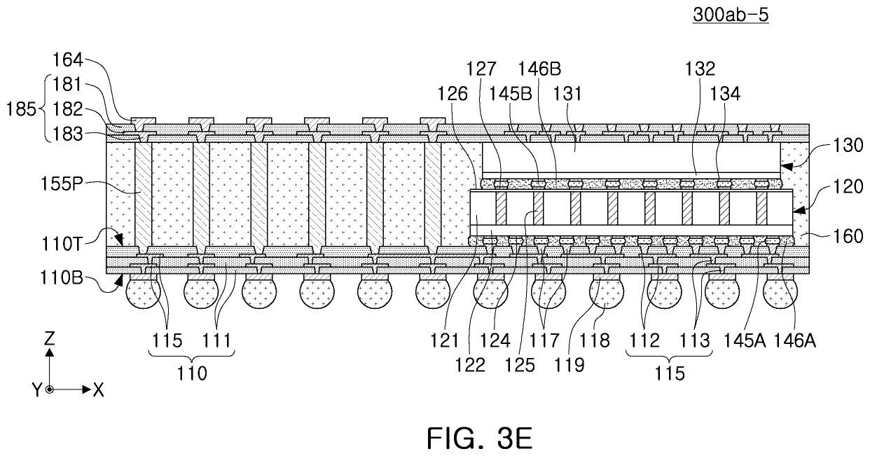

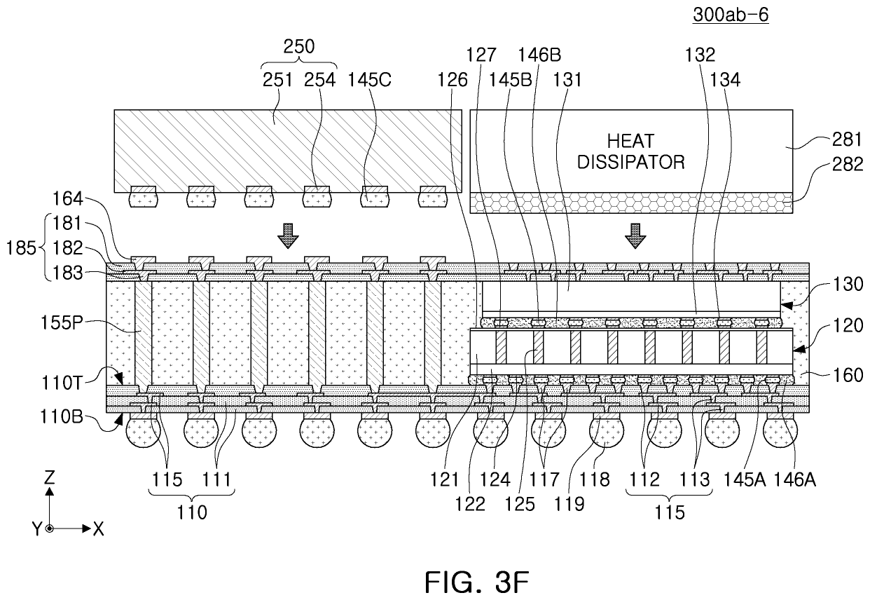

Referring to FIG. 3A, a first operation 300ab-1 of a method of manufacturing a semiconductor package according to an example embodiment of the present disclosure may include forming a first redistribution structure 110 on an upper surface of a carrier substrate 510, and forming first conductive posts 155P on one surface 110T of the first redistribution structure 110.

For example, the carrier substrate 510 may be a detachable copper foil (DCF) carrier substrate. For example, a process of forming the first redistribution layers 112, the first vias 113, and the first conductive posts 155P may use a structure containing an exposable and developable material such as a photoresist.

Referring to FIG. 3B, a second operation 300ab-2 of the method of manufacturing a semiconductor package according to an example embodiment of the present disclosure may include disposing a combination structure of the second and third semiconductor chips 120 and 130 on the one surface 110T of the first redistribution structure 110. Alternatively, the second and third semiconductor chips 120 and 130 may be sequentially disposed in a state of being isolated from each other.

Referring to FIG. 3C, a third operation 300ab-3 of the method of manufacturing a semiconductor package according to an example embodiment of the present disclosure may include filling the encapsulant 160 in a space not occupied by the first conductive posts 155P and the second and third semiconductor chips 120 and 130 on the one surface 110T of the first redistribution structure 110. For example, an upper surface of the encapsulant 160 may be polished such that the upper surface of the third semiconductor chip 130 is upwardly exposed.

Referring to FIG. 3D, a fourth operation 300ab-4 of the method of manufacturing a semiconductor package according to an example embodiment of the present disclosure may include isolating the carrier substrate 510 from the other surface 110B of the first redistribution structure 110, and forming the UBM structures 119 and the first bumps 118 on the other surface 110B of the first redistribution structure 110.

Referring to FIG. 3E, a fifth operation 300ab-5 of the method of manufacturing a semiconductor package according to an example embodiment of the present disclosure may include forming the second redistribution structure 185 on an upper surface of an encapsulant 160. As illustrated in FIG. 1A, the second redistribution structure 185 may be omitted depending on a design thereof.

Referring to FIG. 3F, a sixth operation 300ab-6 of the method of manufacturing a semiconductor package according to an example embodiment of the present disclosure may include disposing the first semiconductor chip 250 and the heat dissipation member 281 on an upper surface of the second redistribution structure 185 (or an upper surface of the encapsulant 160).

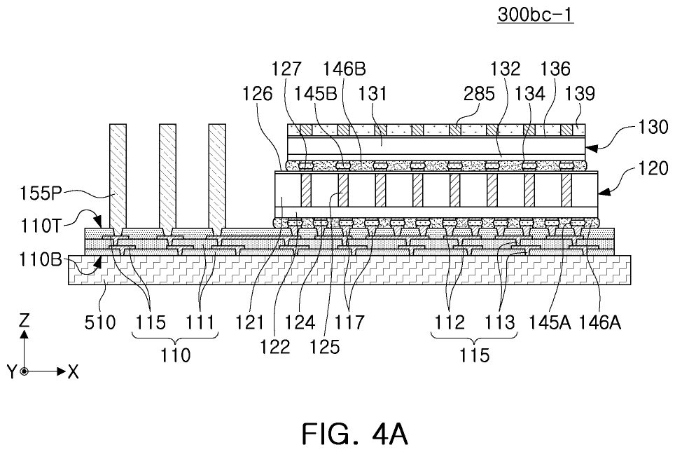

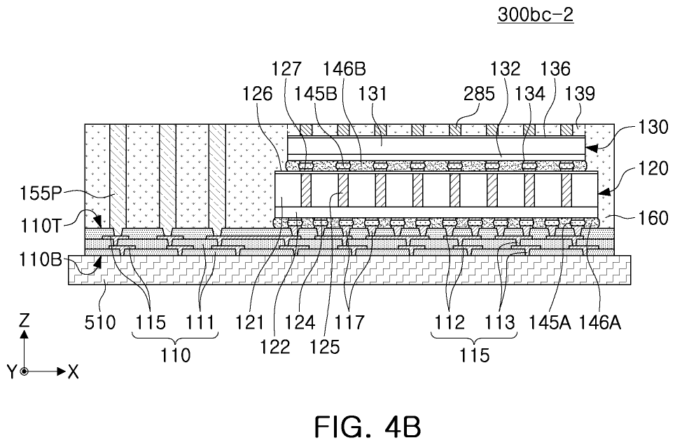

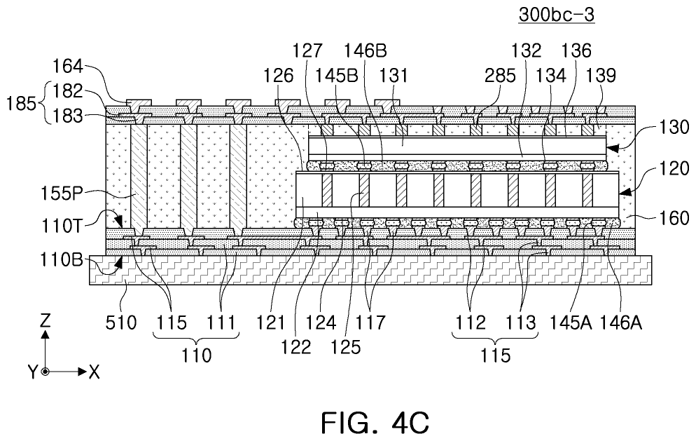

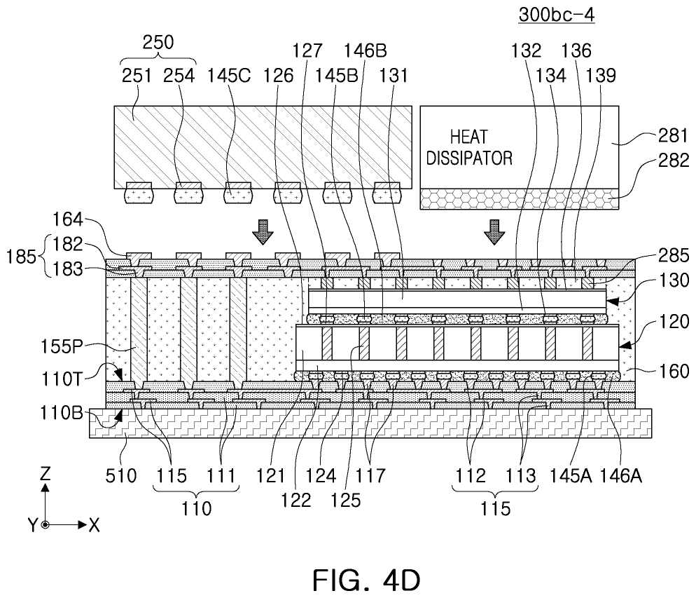

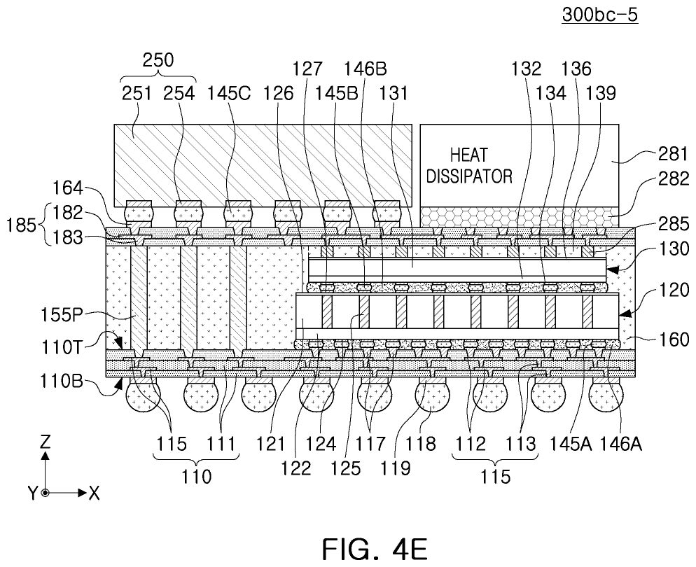

Referring to FIG. 4A, a first operation 300bc-1 of the method of manufacturing a semiconductor package according to an example embodiment of the present disclosure may include forming the first redistribution structure 110 on an upper surface of the carrier substrate 510, and forming the first conductive posts 155P on the one surface 110T of the first redistribution structure 110 and disposing the second and third semiconductor chips 120 and 130. The second conductive posts 285 may be formed before the third semiconductor chip 130 is disposed, or may be formed after the third semiconductor chip 130 is disposed depending on a design thereof.

Referring to FIG. 4B, a second operation 300bc-2 of the method of manufacturing a semiconductor package according to an example embodiment of the present disclosure may include filling the encapsulant 160 in a space not occupied by the first conductive posts 155P and the second and third semiconductor chips 120 and 130 on the one surface 110T of the first redistribution structure 110.

Referring to FIG. 4C, a third operation 300bc-3 of the method of manufacturing a semiconductor package according to an example embodiment of the present disclosure may include forming the second redistribution structure 185 on an upper surface of the encapsulant 160. As illustrated in FIG. 1C, the second redistribution structure 185 may be omitted depending on a design thereof.

Referring to FIG. 4D, a fourth operation 300bc-4 of the method of manufacturing a semiconductor package according to an example embodiment of the present disclosure may include disposing the first semiconductor chip 250 and the heat dissipation member 281 on an upper surface of the second redistribution structure 185 (or an upper surface of the encapsulant 160).

Referring to FIG. 4E, a fifth operation 300bc-5 of the method of manufacturing a semiconductor package according to an example embodiment of the present disclosure may include isolating the carrier substrate 510 from the other surface 110B of the first redistribution structure 110, and forming the UBM structures 119 and the first bumps 118 on the other surface 110B of the first redistribution structure 110.

FIGS. 3A to 4E illustrate formation of one semiconductor package. However, depending on a design thereof, a plurality of semiconductor packages may be collectively formed in a horizontally connected state, and the plurality of semiconductor packages may be isolated from each other by vertical cutting. The semiconductor package of FIGS. 1A to 2C is not construed as being limited by the method of manufacturing a semiconductor package of FIGS. 3A to 4E.

While example embodiments have been shown and described above, it will be apparent to those skilled in the art that modifications and variations could be made without departing from the scope of the present disclosure as defined by the appended claims.

What is claimed is:

1. A semiconductor package comprising:
a first redistribution structure in which at least one first redistribution layer and at least one first insulating layer are alternately stacked;
a first semiconductor chip disposed on an upper surface of the first redistribution structure;
an encapsulant disposed between the first redistribution structure and the first semiconductor chip;
a plurality of first conductive posts electrically connecting the first redistribution structure and the first semiconductor chip with each other, and penetrating through the encapsulant in a first direction;
a heat dissipation member having at least a portion that overlaps the first semiconductor chip in a second direction that is perpendicular to the first direction; and
a second semiconductor chip disposed between the first redistribution structure and the heat dissipation member, and encapsulated by the encapsulant,
wherein the first semiconductor chip overlaps the plurality of first conductive posts in the first direction, and
wherein the first semiconductor chip does not overlap the second semiconductor chip in the first direction.

2. The semiconductor package of claim 1, further comprising:
a third semiconductor chip disposed between the second semiconductor chip and the heat dissipation member, and encapsulated by the encapsulant.

3. The semiconductor package of claim 2,
wherein the encapsulant covers a sidewall of the third semiconductor chip without covering an upper surface of the third semiconductor chip, and
wherein the upper surface of the third semiconductor chip is adjacent to the heat dissipation member, and a lower surface of the third semiconductor chip is adjacent to an upper surface of the second semiconductor chip.

4. The semiconductor package of claim 1,
wherein the plurality of first conductive posts are disposed on a first region of an upper surface of the first redistribution structure, the first region being adjacent to a first sidewall of the first redistribution structure, and
wherein the second semiconductor chip is disposed on a second region of the upper surface of the first redistribution structure, the second region being adjacent to a second sidewall, opposite to the first sidewall, of the first redistribution structure.

5. The semiconductor package of claim 1, further comprising:
a plurality of first bumps disposed on a lower surface of the first redistribution structure, and electrically connected to at least one of the first and second semiconductor chips,
wherein the first and second semiconductor chips are electrically connected with each other through the first redistribution structure.

6. The semiconductor package of claim 1, further comprising:
a plurality of second bumps electrically connecting the plurality of first conductive posts to the first semiconductor chip,
wherein each second bump of the plurality of second bumps overlaps a corresponding first conductive post among the plurality of first conductive posts in the first direction.

7. The semiconductor package of claim 1, further comprising:
a plurality of second conductive posts disposed between the second semiconductor chip and the heat dissipation member,
wherein the plurality of second conductive posts extend from the heat dissipation member toward the second semiconductor chip in the first direction, and
wherein the plurality of second conductive posts thermally connect the second semiconductor chip to the heat dissipation member.

8. The semiconductor package of claim 1, further comprising:
a second redistribution structure disposed between the second semiconductor chip and the heat dissipation member,
wherein the second redistribution structure includes at least one second redistribution layer and at least one second insulating layer that are alternately stacked on each other.

9. A semiconductor package comprising:
a first redistribution structure in which at least one first redistribution layer and at least one first insulating layer are alternately stacked;
a first semiconductor chip disposed on an upper surface of the first redistribution structure;
an encapsulant disposed between the first redistribution structure and the first semiconductor chip;
a plurality of first conductive posts electrically connecting the first redistribution structure and the first semiconductor chip with each other, and penetrating through the encapsulant in a first direction;
a heat dissipation member having at least a portion that overlaps the first semiconductor chip in a second direction that is perpendicular to the first direction;
a second semiconductor chip having at least a portion disposed between the first redistribution structure and the heat dissipation member, and encapsulated by the encapsulant; and
a second redistribution structure disposed between the second semiconductor chip and the heat dissipation member,
wherein the second redistribution structure includes at least one second redistribution layer and at least one second insulating layer that are alternately stacked on each other.

10. The semiconductor package of claim 9,
wherein a portion of the first semiconductor chip overlaps the second semiconductor chip in the first direction.

11. The semiconductor package of claim 9,
wherein a size of a lower surface of the heat dissipation member adjacent to the second semiconductor chip is smaller than a size of a lower surface of the first semiconductor chip adjacent to the first conductive posts.

12. The semiconductor package of claim 9,
wherein the at least one second redistribution layer has a first number of layers, and
wherein the at least one first redistribution layer has a second number of layers, the first number being smaller than the second number.

13. The semiconductor package of claim 9, further comprising:
a third semiconductor chip disposed between the second semiconductor chip and the second redistribution structure, and encapsulated by the encapsulant.

14. The semiconductor package of claim 13,
wherein the encapsulant covers a sidewall of the third semiconductor chip without covering an upper surface of the third semiconductor chip, and
wherein the upper surface of the third semiconductor chip is adjacent to the heat dissipation member, and a lower surface of the third semiconductor chip is adjacent to an upper surface of the second semiconductor chip.

15. The semiconductor package of claim 9,
wherein the plurality of first conductive posts are disposed on a first region of an upper surface of the first redistribution structure, the first region being adjacent to a first sidewall of the first redistribution structure, and
wherein the second semiconductor chip is disposed on a second region of the upper surface of the first redistribution structure, the second region being adjacent to a second sidewall, opposite to the first sidewall, of the first redistribution structure.

16. The semiconductor package of claim 9, further comprising:
a plurality of first bumps disposed on a lower surface of the first redistribution structure, and electrically connected to at least one of the first and second semiconductor chips,
wherein the first and second semiconductor chips are electrically connected with each other through the first redistribution structure.

17. The semiconductor package of claim 9, further comprising:
a plurality of second conductive posts disposed between the second semiconductor chip and the second redistribution structure,
wherein the plurality of second conductive posts extend from the second semiconductor chip to the second redistribution structure in the first direction, and wherein the plurality of second conductive posts thermally connect the second semiconductor chip to the heat dissipation member.

18. A semiconductor package comprising:
a first redistribution structure in which at least one first redistribution layer and at least one first insulating layer are alternately stacked;
a first semiconductor chip disposed on an upper surface of the first redistribution structure;
an encapsulant disposed between the first redistribution structure and the first semiconductor chip;
a plurality of first conductive posts electrically connecting the first redistribution structure and the first semiconductor chip with each other, and penetrating through the encapsulant in a first direction;
a heat dissipation member having at least a portion that overlaps the first semiconductor chip in a second direction that is perpendicular to the first direction;
a second semiconductor chip having at least a portion disposed between the first redistribution structure and the heat dissipation member, and encapsulated by the encapsulant;
a third semiconductor chip disposed between the second semiconductor chip and the heat dissipation member, and encapsulated by the encapsulant; and
a plurality of first bumps disposed on a lower surface of the first redistribution structure, and electrically connected to at least one of the first and second semiconductor chips,
wherein the first and second semiconductor chips are electrically connected with each other through the first redistribution structure,
wherein the plurality of first conductive posts are disposed on a first region of an upper surface of the first redistribution structure, the first region being adjacent to a first sidewall of the first redistribution structure, and
wherein the second semiconductor chip is disposed on a second region of the upper surface of the first redistribution structure, the second region being adjacent to a second sidewall, opposite to the first sidewall, of the first redistribution structure.

19. The semiconductor package of claim 18,
wherein the first semiconductor chip overlaps the plurality of first conductive posts in the first direction,
wherein the first semiconductor chip does not overlap the second and third semiconductor chips in the first direction,
wherein the encapsulant covers a sidewall of the third semiconductor chip without covering an upper surface of the third semiconductor chip, and
wherein the upper surface of the third semiconductor chip is adjacent to the heat dissipation member, and a lower surface of the third semiconductor chip is adjacent to an upper surface of the second semiconductor chip.

20. The semiconductor package of claim 18, further comprising:
a second redistribution structure disposed between the third semiconductor chip and the heat dissipation member,
wherein the second redistribution structure includes at least one second redistribution layer and at least one second insulating layer that are alternately stacked on each other,
wherein a portion of the first semiconductor chip overlaps the second semiconductor chip in the first direction, and
wherein a size of a lower surface of the heat dissipation member adjacent to the second semiconductor chip is smaller than a size of a lower surface of the first semiconductor chip adjacent to the first conductive posts.
